(19) United States
(12) Patent Application Publication
(10) Pub. No.: US 2026/0018518 A1
(43) Pub. Date: Jan. 15, 2026

(54) BACKSIDE TRENCH ISOLATION FOR HIGH VOLTAGE DEVICE INTEGRATION

(71) Applicant: INTERNATIONAL BUSINESS MACHINES CORPORATION, ARMONK, NY (US)

(72) Inventors: Gopal Sankar Kenath, Troy, NY (US); Tao Li, Slingerlands, NY (US); Ruilong Xie, Niskayuna, NY (US); Robert Gauthier, Williston, VT (US)

(21) Appl. No.: 18/773,493

(22) Filed: Jul. 15, 2024

(51) Int. Cl. H01L 23/528; H01L 21/762; H01L 21/8234; H01L 23/522; H01L 27/06; H01L 29/06; H01L 29/423; H01L 29/775; H01L 29/78; H01L 29/786

(52) U.S. Cl. CPC H01L 23/5286; H01L 21/76229; H01L 23/5226; H10D 62/115; H10D 84/0151; H10D 84/038; H10D 84/40; H10D 30/43; H10D 30/62; H10D 30/6735; H10D 30/6757; H10D 62/121

(57) ABSTRACT

A semiconductor device includes a backside contact, a shallow trench isolation (STI), and a backside dielectric trench isolation (BDTI) below the STI. A top surface of the BDTI is connected to the STI on a backside of a high voltage region of the semiconductor device, a bottom surface of the BDTI is connected to a backside power interconnect, and the BDTI isolates a backside contact from a substrate.

### BACKGROUND

### Technical Field

The present disclosure generally relates to semiconductors, and more particularly, to semiconductors with backside isolation trench for high voltage device integration structure, and methods of creation thereof.

### Description of Related Art

The relentless miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a backside contact, a shallow trench isolation (STI), and a backside dielectric trench isolation (BDTI) below the STI. A top surface of the BDTI is connected to the STI on a backside of a high voltage region of the semiconductor device, a bottom surface of the BDTI is connected to a backside power interconnect, and the BDTI isolates a backside contact from a substrate.

In one embodiment, the semiconductor device includes a bonding oxide bonding the semiconductor device to a carrier wafer, and a bottom interlayer dielectric isolating the substrate from contact with the backside interconnect.

In one embodiment, the backside contact includes a backside via connected to a frontside via, the STI covers lower portions of sidewalls of the frontside via, and the BDTI covers sidewalls of the backside via.

In one embodiment, the semiconductor device includes an oxide layer over lower portions of sidewalls of the STI and over the BDTI, and an insulating layer over sidewalls of the frontside via. The insulating layer isolates the frontside via from direct contact with the STI.

In one embodiment, the semiconductor device includes a first source/drain region and a second source/drain region over the substrate, and a second frontside contact connecting the second source/drain region to a back end of line (BEOL) through a via. A first frontside contact connects the first source/drain region to a backside of the semiconductor through the frontside via and the backside via.

In one embodiment, the high voltage region is a fin field-effect transistor (FET), a planar device, or a nanosheet transistor.

In one embodiment, the bottom surface of the BDTI and a bottom surface of the backside via are coplanar.

In one embodiment, the semiconductor device includes a passive device, and an active device connected to the passive device.

In one embodiment, the insulating layer isolates the frontside via from direct contact with gate regions of the active device.

According to an embodiment, a method for fabrication of a semiconductor device includes forming a backside contact, forming a shallow trench isolation (STI), forming a backside dielectric trench isolation (BDTI) below the STI, establishing a connection between a top surface of the BDTI and the STI on a backside of a high-voltage region of the semiconductor device, establishing a connection between a bottom surface of the BDTI and a backside power interconnect, and isolating a backside contact from a substrate by the BDTI.

In one embodiment, the method includes bonding the semiconductor device to a carrier wafer via a bonding oxide, and isolating the substrate from contact with the backside interconnect via a bottom interlayer dielectric.

In one embodiment, the backside contact includes a backside via connected to a frontside via. The method further includes covering lower portions of sidewalls of the frontside via by the STI, and covering sidewalls of the backside via by the STI.

In one embodiment, the method includes forming an oxide layer over lower portions of sidewalls of the STI and over the BDTI, forming an insulating layer over sidewalls of the frontside via, and isolating the frontside via from direct contact with the STI by the insulating layer.

In one embodiment, the method includes forming a first source/drain region and a second source/drain region over the substrate, establishing a connection between the second source/drain region to a back end of line (BEOL) through a second frontside contact and a via, and establishing a connection between the first source/drain region to a backside of the semiconductor through a frontside contact, the frontside via and the backside via.

In one embodiment, the high voltage region is a fin field-effect transistor (FET), a planar device, or a nanosheet transistor.

In one embodiment, the bottom surface of the BDTI and a bottom surface of the backside via are coplanar.

In one embodiment, the method includes forming a passive device, and forming an active device connected to the passive device.

In one embodiment, the method includes isolating the frontside via from direct contact with gate regions of the active device by the insulating layer.

According to an embodiment, a semiconductor device includes a shallow trench isolation (STI), and a backside dielectric trench isolation (BDTI) below the STI. A top surface of the BDTI is connected to the STI on a backside of a high voltage region of the semiconductor device, a bottom surface of the BDTI is connected to a backside power interconnect, and the high voltage region is a fin field-effect transistor (FET), a planar device, or a nanosheet transistor.

In one embodiment, the semiconductor device includes a backside contact. The BDTI isolates a backside contact from a substrate.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1C illustrate an active device of a semiconductor device, in accordance with some embodiments.

FIG. 1D illustrates top views of a semiconductor device, in accordance with some embodiments.

FIGS. 2A-2C illustrate a semiconductor device after the middle of line and the back end of line processes, consistent with an illustrative embodiment.

FIGS. 3A-3C illustrate a semiconductor device after the wafer flipping and substrate removal, in accordance with some embodiments.

FIGS. 4A-4C illustrate a semiconductor device after the after the removal of the etch stop layer, in accordance with some embodiments.

FIGS. 5A-5C illustrate a semiconductor device after the patterning of the backside via, in accordance with some embodiments.

FIGS. 6A-6C illustrate a semiconductor device after the formation of the oxide layer, in accordance with some embodiments.

FIGS. 7A-7C illustrate a semiconductor device after the formation of the backside trench isolation, in accordance with some embodiments.

FIGS. 8A-8C illustrate a semiconductor device after the formation of the backside contact, in accordance with some embodiments.

FIGS. 9A-9C illustrate a semiconductor device after the formation of the backside interconnect, in accordance with some embodiments.

FIG. 10 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

The concepts herein relate to semiconductor devices with backside trench isolation for high voltage device integration. Deep trench isolation is a technique employed in semiconductor device fabrication to electrically isolate certain devices, such as high voltage devices, from surrounding areas. This isolation is achieved by etching deep trenches into the silicon substrate and filling them with an insulating material, typically silicon dioxide. The deep trenches create a physical barrier that prevents electrical crosstalk and interference between the isolated device and other components on the chip. This isolation is particularly important in mixed-signal and high-voltage applications, where the presence of high electric fields can adversely affect the performance of nearby low-voltage or sensitive analog components.

Disclosed is a semiconductor device that enables high voltage device integration though a fully depleted bulk process (FVBP) scheme by utilizing a backside trench isolation. The patterning of backside vias (BVs) can be leveraged for multiple purposes; for instance, the connection of the backside power delivery network (BSPDN) to the frontside via. The disclosed semiconductor device enables the BSPDN to efficiently distribute power across the semiconductor device, particularly in advanced nodes where power integrity is critical. By patterning the backside vias, a direct electrical pathway is established, enabling seamless power delivery from the backside to the frontside of the wafer. This connectivity enhances the overall power distribution network, ensuring that various components receive stable and adequate power supply.

The semiconductor can provide a way to form backside trench isolation which involves creating deep trenches in the substrate to electrically isolate certain regions of the semiconductor device, particularly those handling high voltages. This technique ensures that electrical interference, crosstalk, and leakage currents are minimized, which is essential for the reliable operation of high-performance devices.

Additionally, the disclosed semiconductor device can facilitate the formation of backside trench isolation during the FVBP process, by patterning the backside vias. Such an approach involves creating trenches on the backside of the wafer, which are then filled with an insulating material to provide electrical isolation. Backside trench isolation can be useful for isolating high-voltage devices or other sensitive components that require robust isolation from the rest of the circuitry. The integration of backside trench isolation with backside via patterning in the disclosed semiconductor device can streamline the fabrication process, allowing for the simultaneous creation of isolation structures and electrical connections.

The dual functionality of backside via patterning in the FVBP process offered by the disclosed semiconductor device can simplify the manufacturing workflow and enhance the efficiency of the semiconductor device. Further by combining the formation of BSPDN connections and backside trench isolation, the process reduces the need for additional masking steps and complex alignments. This consolidation not only saves time and resources but also minimizes potential sources of errors, thereby improving the yield and reliability of the final semiconductor product.

Even further, the disclosed semiconductor device utilizes the use of deep trench isolation and backside via patterning in conjunction with the FVBP process, which supports the development of high-performance semiconductor devices with advanced capabilities. The enhanced isolation provided by deep trench structure and the efficient power distribution enabled by backside vias contribute to the overall robustness and functionality of the semiconductor device.

The process of forming these trenches typically involves several key steps. Initially, an etching process is used to create deep trenches in the silicon substrate. These trenches are designed to penetrate the substrate to a significant depth, ensuring thorough isolation between the device regions. The etching can be achieved using reactive ion etching (RIE), a technique that allows for precise control over the trench dimensions and depth. Once the trenches are etched, they are filled with an insulating material, such as silicon dioxide or another dielectric substance. The filling process can be carried out using chemical vapor deposition (CVD) or other suitable deposition methods. The insulating material can fill the trenches, creating a barrier that prevents electrical interaction between the isolated regions. Excess material on the surface can be removed using chemical mechanical planarization (CMP), which ensures a smooth and planar surface.

In the FVBP process, backside vias (BVs) are patterned to connect the BSPDN to the frontside vias. This patterning step can be leveraged to simultaneously form the backside trench isolation, integrating both processes seamlessly.

During the FVBP flow, after the frontside device fabrication steps are completed, the wafer is flipped to process the backside. At this stage, the backside vias are patterned and etched to establish electrical connections to the frontside. Using the same lithographic and etching tools, the deep trenches for backside isolation can be defined and etched. This concurrent patterning and etching not only streamline the process but also ensures precise alignment between the backside vias and the isolation trenches.

Once the backside vias and isolation trenches are etched, the trenches are filled with the insulating material, as previously described. The integration of trench filling and via formation ensures that the backside isolation is robust while maintaining the integrity of the electrical connections between the frontside and backside. This co-integration approach minimizes additional process steps and equipment usage, enhancing overall efficiency and yield.

Accordingly, the teachings herein provide methods and systems of semiconductor device formation with backside trench isolation for high voltage device integration. The techniques described herein may be implemented in a number of ways. Example implementations are provided below with reference to the following figures.

### Example Semiconductor Device With Backside Trench Isolation for High Voltage Device Integration Structure

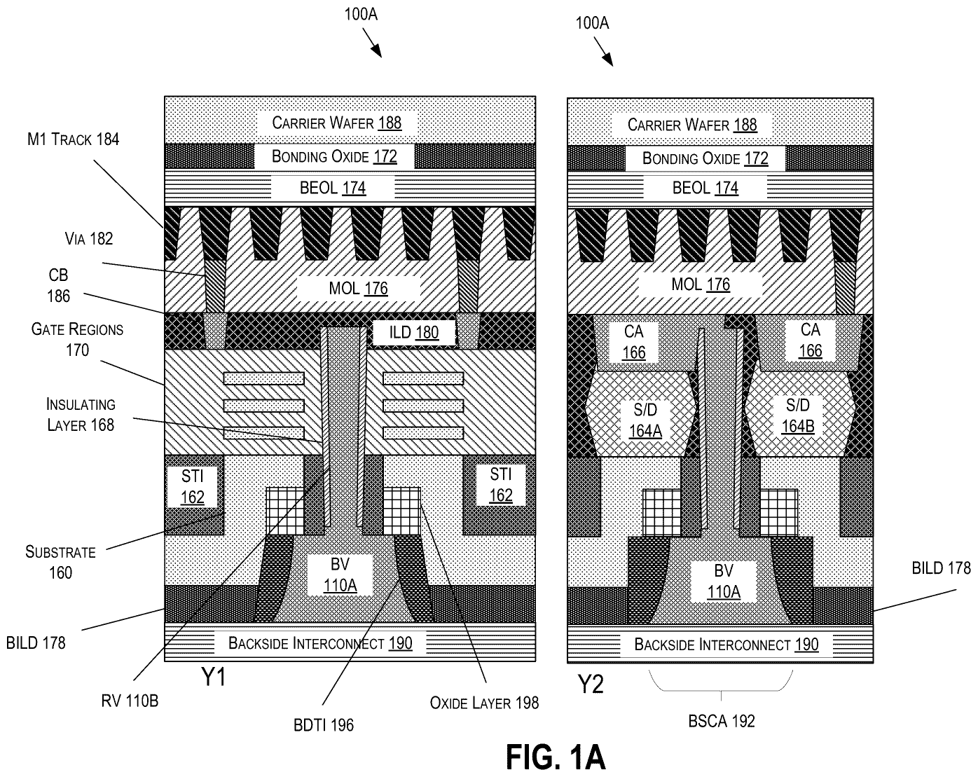

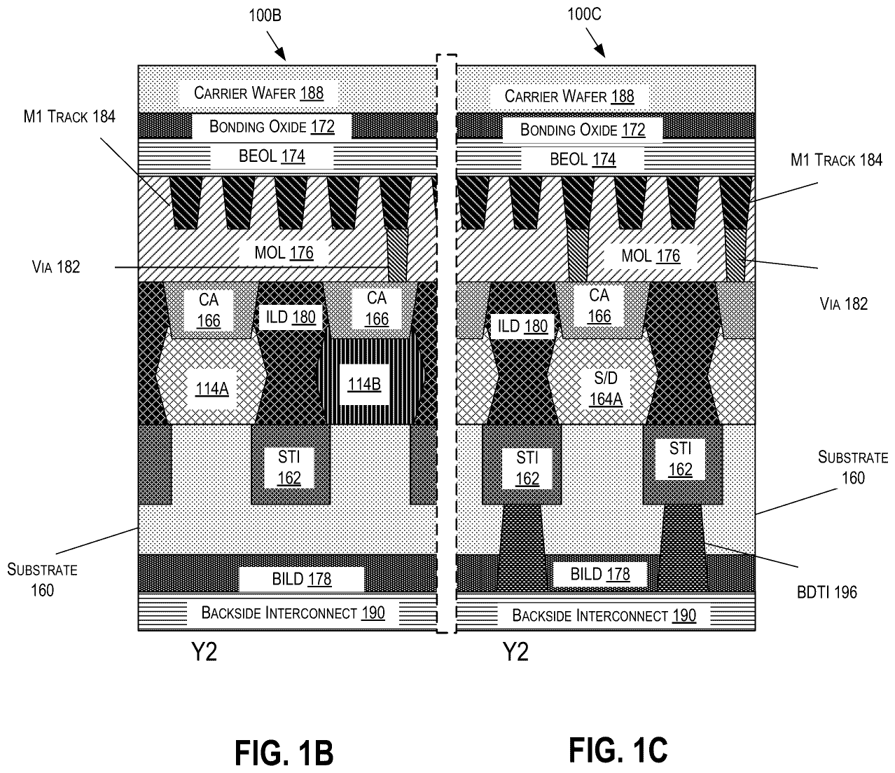

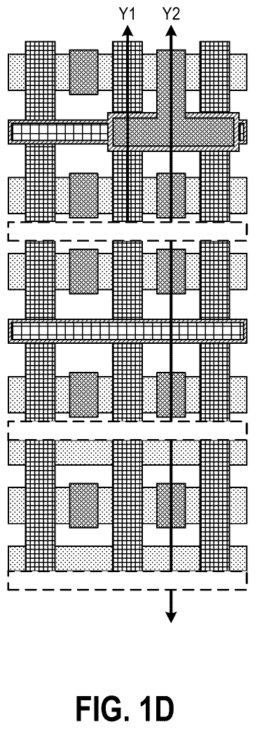

Reference now is made to FIGS. 1A-1C, which are simplified cross-sections view of a semiconductor device, consistent with an illustrative embodiment. In various embodiments, the semiconductor device includes an active device 100A, a passive device 100B, and a high voltage region 100C. While for the sake of simplicity, the active device 100A, the passive device 100B, and the high voltage region 100C are depicted separately, it should be noted that the active device 100A, the passive device 100B, and the high voltage region 100C can be integrated on a same semiconductor device adjacent to each other.

Referring to FIGS. 1A-1D, the active device of the semiconductor device is illustrated. The active device 100A, which can be a transistor, can include a substrate 160, a shallow trench isolation, STI 162, a first source/drain region, S/D 164A, a second source/drain region, S/D 164B, source/drain contacts, CA 166, an insulating layer 168, gate regions 170, a bonding oxide 172, back end of line, BEOL 174, middle of line, MOL 176, a bottom interlayer dielectric, BILD 178, interlayer dielectric, ILD 180, a via 182, a metal line, M1 track 184, gate contacts, CB 186, a carrier wafer 188, a backside interconnect 190, a backside contact, BSCA 192, a backside dielectric trench isolation, BDTI 196, and an oxide layer 198.

The substrate 160 can be composed of silicon and can provide the mechanical support necessary for the integrated circuit's construction. In some embodiments, the substrate 160 can extend below the S/D 164A, the S/D 164B, and the gate regions 170.

The STI 162 can be used to electrically isolate individual components and other components on the active device 100A. The STI 162 can be made by etching narrow trenches into the substrate 160 and then filling these trenches with an insulating material, usually silicon dioxide. This process can prevent electrical interference between adjacent components, which can help maintain the integrity of signals and ensure proper device functionality.

Generally, the source/drain regions, such as the S/D 164A and S/D 164B, are salient components that play relevant roles in the semiconductor device's operation. In various embodiments, the S/D 164A and S/D 164B are region within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

In some embodiments, while the S/D 164A is connected to the backside of the active device 100A through the CA 166, RV110B and BV 110A, S/D 164B is connected to the BEOL 140 through the CA 166 and the via 182. Thus, while a pathway for electrical signals to travel from the S/D 164B to the backside interconnect 190 is formed, a pathway for electrical signals to travel from the S/D 164B to the BEOL 174 is also formed.

The CA 166, located over the S/D 164A and S/D 164B, can establish connections between the S/D 164A and S/D 164B and the MOL 176 and the BEOL 174. The CA 166 can ensure efficient electrical routing and connectivity within the active device 100A. The fabrication of the CA 166 can involve lithography and etching processes to define the contact area. The CA 166 can be made using conductive materials such as copper (Cu) or tungsten (W).

In various embodiments, the gate regions 170 serve as control elements that regulate the flow of current through the active device 100A. The gate regions 170 can be composed of a conductive material. The gate regions 170 can control the flow of electric current between the source and drain regions. In addition to acting as a switch, modulating the gate voltage can enable the gate regions 170 to control the current flowing through the channel region, resulting in amplified output signals.

In an embodiment, the gate regions 170 can enable the implementation of Boolean logic operations, such as AND, OR, and NOT, by controlling the flow of current based on the input voltages. In some embodiments, the gate regions 170, along with other active device components, can facilitate the miniaturization and integration of electronic circuits. The ability to control the channel region's conductivity through the gate voltage allows for compact and highly efficient circuit designs.

In several embodiments, the BILD 178 can provide structural support to the semiconductor device by maintaining the mechanical integrity and stability of the active device 100A. The BILD 178 can further help prevent the warping, bending, or cracking of the substrate, particularly during the manufacturing process or subsequent handling. The BILD 178 can ensure that the active device 100A remains mechanically robust and maintains its dimensional stability.

In an embodiment, the BILD 178 can also serve as a planarization layer in the active device 100A fabrication process. As various layers are deposited and patterned on the front side of the active device 100A, irregularities or topographic variations may arise. The BILD 178 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 178 can contribute to improved overall semiconductor device performance. In several embodiments, BILD 178 can facilitate wafer-level testing of the semiconductor device. By providing electrical isolation between the active regions and the backside contact, individual active device or elements on the active device 100A can be electrically accessed and tested without interference from neighboring devices or components. This enables efficient and accurate wafer-level testing, ensuring quality control during semiconductor manufacturing.

The ILD 180 can be a layer of insulating material to electrically isolate and provide mechanical support between different layers of conducting and active components. The ILD 180 can enable efficient signal transmission, reduce crosstalk, and ensure the proper functioning of the active device 100A. In an embodiment, the ILD 180 can electrically isolate adjacent conducting layers or active components in the active device 100A. By providing insulation between different layers, the ILD 180 can prevent electrical shorts, reduce (e.g., minimize) leakage current, and ensure that signals are directed only along the desired pathways. In some embodiments, the ILD 180 can help reduce parasitic capacitance between adjacent metal interconnects or active devices and provide mechanical support to the active device's structure.

The bonding oxide 172 can be employed to facilitate the bonding of different layers or wafers, i.e., the active device 100A to the carrier wafer 188. The bonding oxide 172 can be composed of silicon dioxide and can act as an intermediary that ensures strong adhesion between the bonded surfaces. In some embodiments, the bonding oxide 172 can serve as an insulating layer, preventing electrical conduction between the bonded layers.

The BEOL 174 can include metal interconnects and other structures on the upper layers of an active device 100A to form a network of connections that link various components of the active device 100A.

The MOL 176 can connect the BEOL 174 to the other components of the active device 100A and include contacts and local interconnects that connect the transistor to the first level of metal interconnects. In some embodiments, the MOL 176 can include contact vias, such as via 182, and the M1 track 184. The via 182 can be an opening or hole in the active device 100A that allows for vertical electrical connections between different metal layers. The via 182 can be used to create a multi-layer interconnect structure. The M1 track 184 can be the first layer of metal interconnects in the active device 100A, and form the routing paths for electrical signals between different components on the active device 100A.

The CB 186 are the conductive connections that link the gate electrodes of the active device 100A to the interconnect network. The CB 186 can be formed using materials such as tungsten or copper, deposited into contact holes etched in the insulating layers.

The carrier wafer 188 can be used as a temporary support for handling the active device 100A during semiconductor processing and provide mechanical stability and protection during various fabrication steps, such as thinning, bonding, and dicing. The carrier wafer 188 can be eventually removed, leaving the active device 100A ready for packaging. The backside interconnect can be a metal interconnect formed on the backside of an active device 100A for power distribution, signal routing, or thermal management.

The BSCA 192 is a region on the backside of the active device 100A where electrical connections are made. By establishing the electrical contacts, the BSCA 192 can ensure the proper functioning of the active device 100A and facilitates electrical signal transmission. The BSCA 192 can serve as a thermal interface between the active device 100A and a heat sink or other cooling mechanisms. By establishing direct contact with the substrate, the BSCA 192 can conduct the heat away from the active device 100A, and contribute to improved thermal dissipation. In some embodiments, the BSCA 192 can help mitigate parasitic effects, such as substrate coupling or substrate noise, from the active device 100A. In further embodiments, the BSCA 192 can allow for increased integration density in the active device 100A.

In some embodiments, the BSCA 192 can include a lower portion, i.e., BV 110A and an upper portion, i.e., RV 110B. The RV 110B can be a frontside via connecting the CA 166, and hence the S/D 164A, to the backside via, i.e., BV 110A, and hence the backside interconnect 190 and to the backside of the active device 100A.

In some embodiments, the insulating layer 168 can cover the sidewalls of the RV 110B, isolating the RV 110B from direct contact with the STI 162. This configuration ensures that the RV 110B remains electrically isolated, preventing leakage or crosstalk between the RV 110B and the STI 162.

In some embodiments, the insulating layer 168 can isolate the RV 110B from direct contact with the gate regions 170 on the active device 100A, ensuring that the active device 100A operates without interference from the RV 110B. This isolation can facilitate maintaining the performance and reliability of the active device 100A, particularly in high-speed and high-frequency applications.

The BDTI 196 can be positioned below the STI 162 to provide enhanced electrical isolation in the semiconductor devices. The BSCA 192 can include a backside via, BV 110A, that is connected to a frontside via, RV 110B. The RV 110B can be extending vertically and can connect the BV 110A to the CA 166, which is connected to the S/D 164A. As such, the S/D 164A is connected to the backside of the active device 100A. The STI 162 can cover the lower portions of the sidewalls of the RV 110B, ensuring electrical isolation and structural integrity. Additionally, the BDTI 196 can cover the sidewalls of the BV 110A, providing further isolation and preventing electrical interference between the different layers of the semiconductor device. In some embodiments, the bottom surface of the BDTI 196 and the bottom surface of the BV 110Acan be coplanar, ensuring a uniform and stable structure. This coplanarity can facilitate maintaining the integrity and reliability of the semiconductor device, such as during thermal cycling and other stress-inducing processes.

In some embodiments, the oxide layer 198 can cover the lower portions of the sidewalls of the STI 162 and the BDTI 196. The oxide layer 198 can enhance the insulating properties and ensure that the electrical isolation is maintained throughout the active device 100A.

Reference is now made to FIG. 1B, where a passive device of a semiconductor device is illustrated, according to some embodiments. In some embodiments, the passive device 100B can include a first doped region 114A, a second doped region 114B, CA 166, MOL 176, BEOL 174, BILD 178, ILD 180, a carrier wafer 188, a substrate 160, STI 162, a bonding oxide 172, a via 182, a metal line, M1 track 184, and a backside interconnect 190. As can be seen, the passive device 100B does not include BSCA, BDTI, or oxide layer.

Reference is now made to FIG. 1C, where a high voltage region of a semiconductor device is illustrated, according to some embodiments. In some embodiments, the high voltage region 100C can include a first S/D 164A, CA 166, MOL 176, BEOL 174, BILD 178, ILD 180, a carrier wafer 188, a substrate 160, STI 162, a bonding oxide 172, a via 182, a metal line, M1 track 184, a backside interconnect 190, and BDTI 196.

In various embodiments, the high voltage region 100C can be a fin field-effect transistor (FET), a planar device, or a nanosheet transistor. The different types of high voltage regions can cater to various applications and performance requirements, providing flexibility in the design and functionality of the semiconductor device.

In some embodiments, the top surface of the BDTI 196 can be connected to the STI 162 on the backside of the high voltage region 100C. This connection can facilitate maintaining continuity in the isolation between the frontside and the backside of the semiconductor device. The STI 162 can isolate the high voltage region 100C on the frontside, while the BDTI 196 can extend such an isolation to the backside, ensuring that the high voltage region 100C does not interfere with other device regions.

In some embodiments, the bottom surface of the BDTI 196 can be connected to the backside interconnect 190. The backside interconnect 190 can be part of the BSPDN 194. The connection between the BDTI 196 and the backside interconnect 190 can ensure that the power delivery network remains isolated from the high voltage regions 100C, preventing crosstalk or electrical interference that can degrade the performance of the semiconductor device.

In some embodiments, the BDTI 196 can serve to isolate the BSCA 192 from the substrate 160. The substrate 160 can form the base layer of the semiconductor device, and direct contact with high voltage region 100C can lead to unwanted current paths and leakage. By isolating the BSCA 192 from the substrate 160, the BDTI 196 can ensure that the electrical properties of the high voltage region 100C do not adversely affect the overall device. This isolation can help maintain the integrity of the electrical signals and prevent degradation in the performance of the semiconductor device. FIG. 1D illustrates top views of the semiconductor device as shown in IFGS. 1A-1C.

### Example Fabrication of Semiconductor Device With Backside Trench Isolation for High Voltage Device Integration

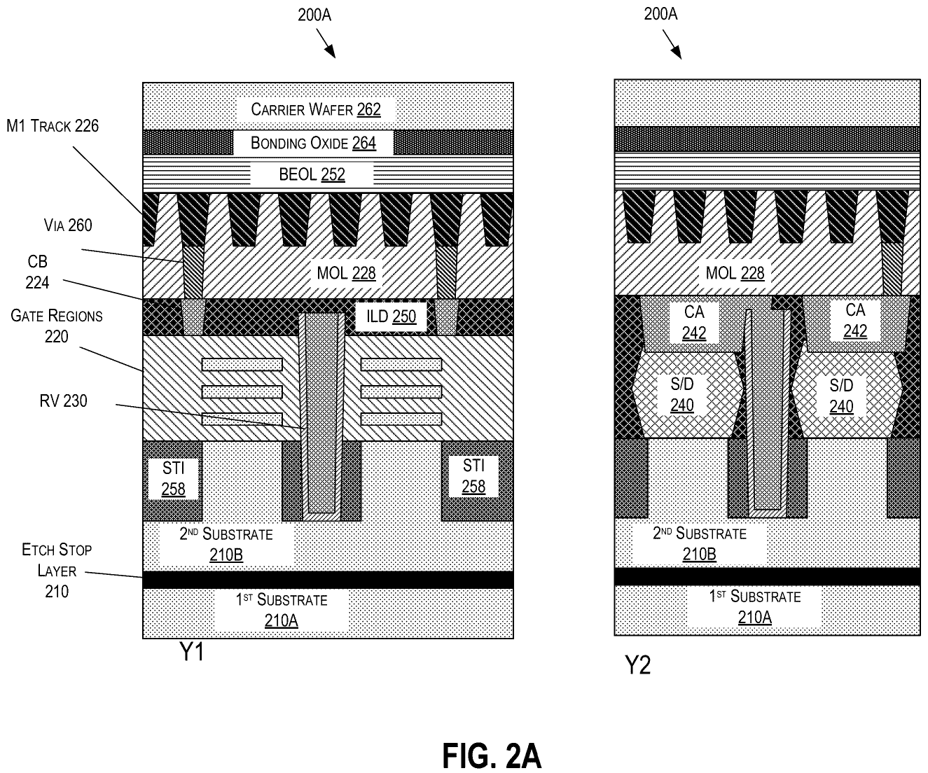

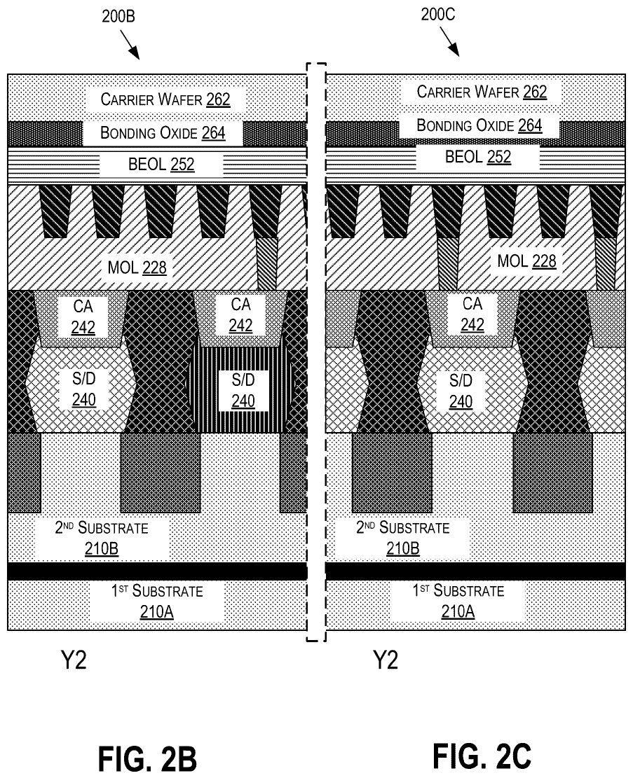

With the foregoing description of an example semiconductor device, it may be helpful to discuss an example process of manufacturing the same. To that end, FIGS. 2-9 illustrate various acts in the manufacture of a semiconductor device, consistent with illustrative embodiments. Figures denoted by A show the acts of fabrication of the active device, figures denoted by B show the acts of fabrication of the passive device, and figures denoted by C illustrate the acts of fabrication of the high voltage region.

Reference now is made to FIGS. 2A-2C, which are simplified cross-section views of a semiconductor device after the middle of line and back end of line process, in accordance with some embodiments.

The semiconductor device, i.e., the active device 200A, the passive device 200B, and the high voltage region 200C, can include gate regions 220, source/drain regions, S/D 240, frontside contacts, CA 242, ILD 250, BEOL 252, STI 258, a via 260, a carrier wafer 262, a bonding oxide 264, a first substrate 210A, a second substrate 210B and an etch stop layer 212, gate contacts, CB 224, M1 track 226, MOL 228, and RV 230.

In the illustrative example depicted in FIGS. 2A-2B, the semiconductor device is depicted as being on silicon as the first substrate 210A and the second substrate 210B, while it will be understood that other types as the first substrate 210A and the second substrate 210B may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 210A and the second substrate 210B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 210 is formed over the first substrate 210A. The etch stop layer 210 can be a thin layer of material incorporated into the structure of the semiconductor device to provide a selective barrier against etching processes, preventing further removal of underlying materials during fabrication. The etch stop layer 210 can enable precise control over the etching depth and help define the desired device dimensions. The etch stop layer 210 can further provide a stopping point for the etching process, ensuring that specific layers or regions are not etched beyond a certain point, leading to accurate patterning and control of critical features. The etch stop layer 210 can create a distinct separation between different layers or components within the device structure, and prevent the undesired etching of underlying layers or materials, enabling the creation of complex, multi-layered structures with well-defined interfaces and boundaries. In some embodiments, the etch stop layer 210 acts as a protective barrier for sensitive or delicate materials to shield such materials from aggressive etchants, preventing damage or degradation during subsequent fabrication steps.

In some embodiments, prior to forming the etch stop layer 210, the first substrate 210A is prepared by cleaning and removing any impurities or oxide layers. The etch stop layer 208 is deposited onto the first substrate 210A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 210 can then be selectively etched, stopping at a predetermined depth, while protecting the underlying layers. After the etching process, the remaining photoresist can be removed through stripping techniques. While in some embodiments, SiGe is used to form the etch stop layer 210, in some embodiments, silicon nitride (SiN), silicon oxide (SiO2), or silicon oxynitride (SiON) can be used as the etch stop layer 210.

In some embodiments, the STI 258 can be made of SiN. The ILD 232 can be made of SiO2. The gate regions 220 can be formed over the active device 200A. A replacement metal gate (RMG) process can be used to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability.

In some embodiments, a bonding oxide 264 is formed over the BEOL 252. A carrier wafer 262 is bonded to the active device 200A via the bonding oxide 264. In some embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

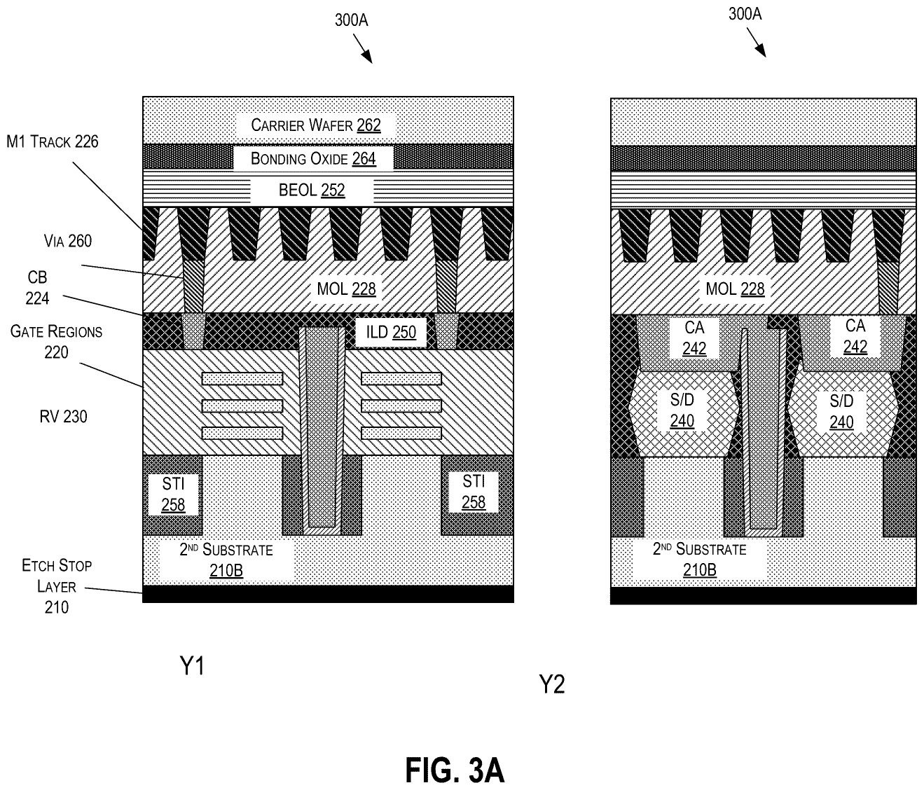

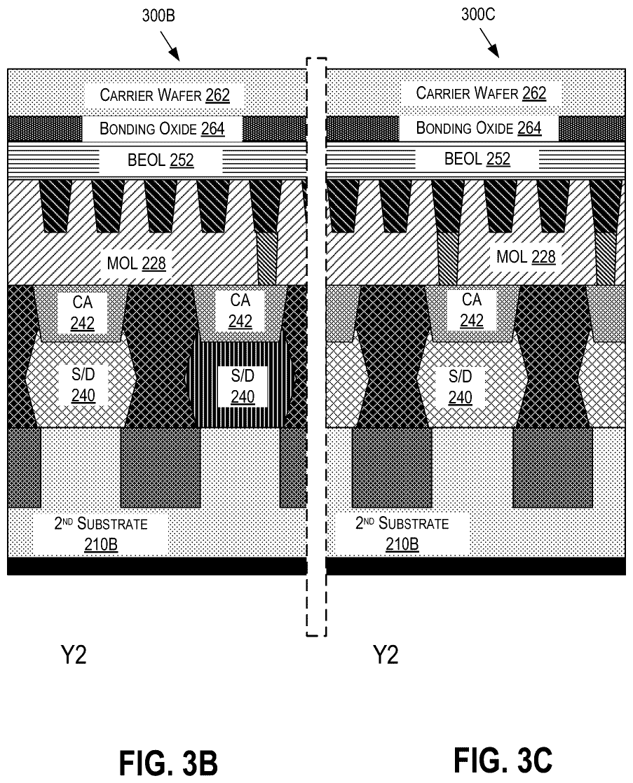

FIGS. 3A-3C illustrate a semiconductor device after the wafer flip and removal of the first substrate, in accordance with some embodiments. In some embodiments, the wafer is flipped and the first substrate is removed. A CMP process can be performed on the semiconductor device. It should be noted that, for the sake of simplicity, the semiconductor device is not shown as flipped in FIGS. 3A-3C. The first substrate removal stops at the etch stop layer 212.

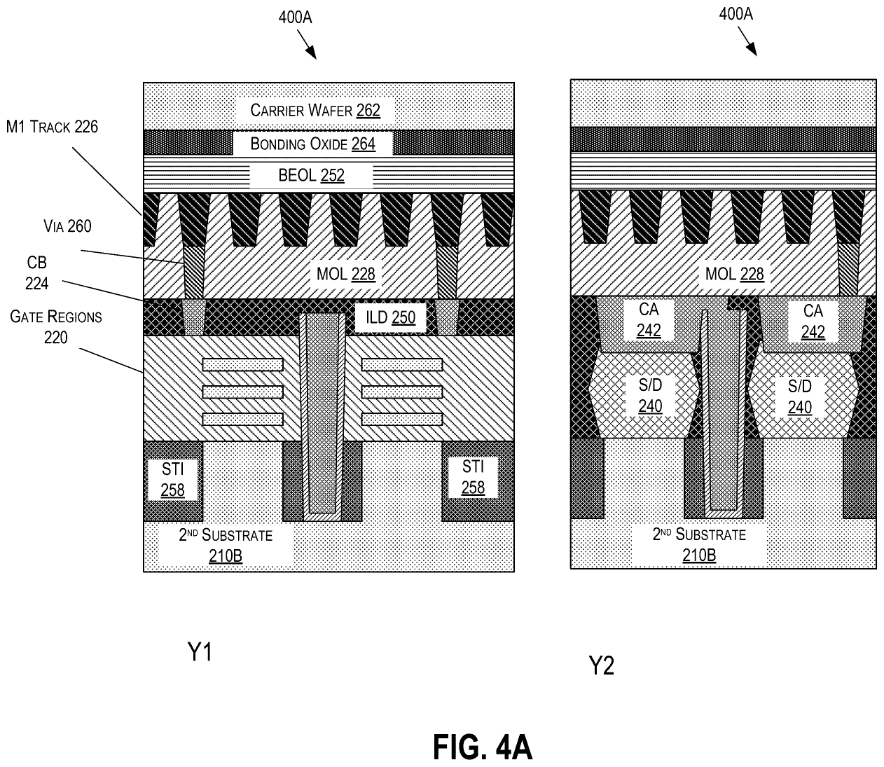

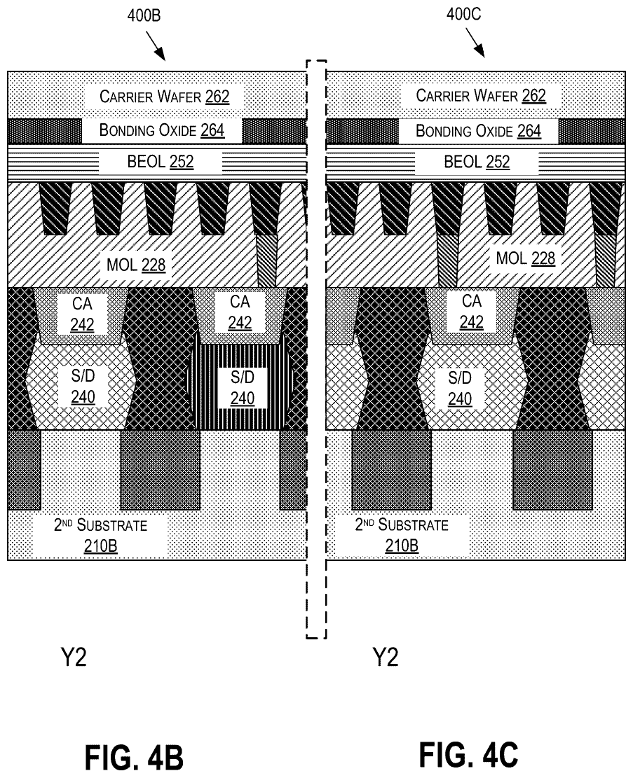

FIGS. 4A-4C illustrate a semiconductor device after the removal of the etch stop layer, in accordance with some embodiments. In some embodiments, the etch stop layer is removed from the semiconductor device to expose the second substrate 210B.

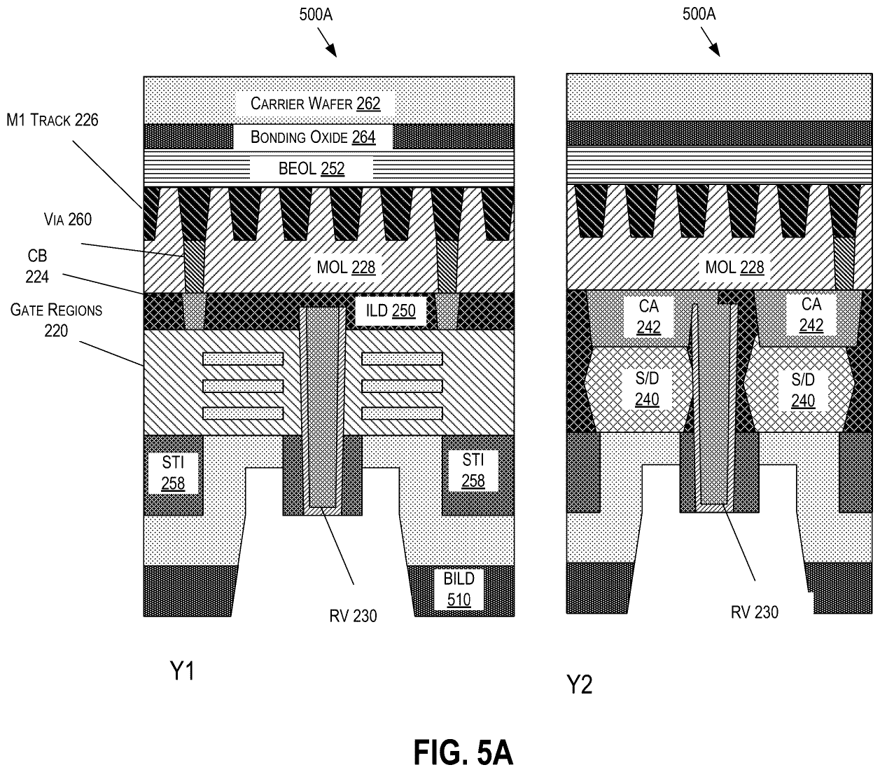

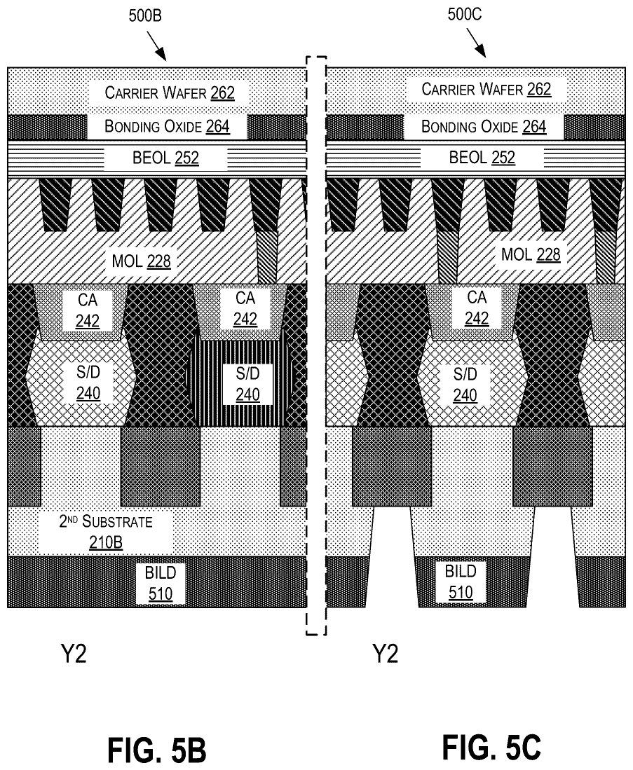

FIGS. 5A-5C illustrate a semiconductor device after the pattering of the backside via, in accordance with some embodiments. In some embodiments, a bottom interlayer dielectric, BILD 510, is formed over the second substrate 212B of the active device 500A and the high voltage region 500C. Subsequently, portions of the BILD 510 and the second substrate 212B are removed to expose the STI 258 and the RV 230. The passive device 500B remains intact, i.e., by being covered by an organic planarization layer (OPL) or a hard mask.

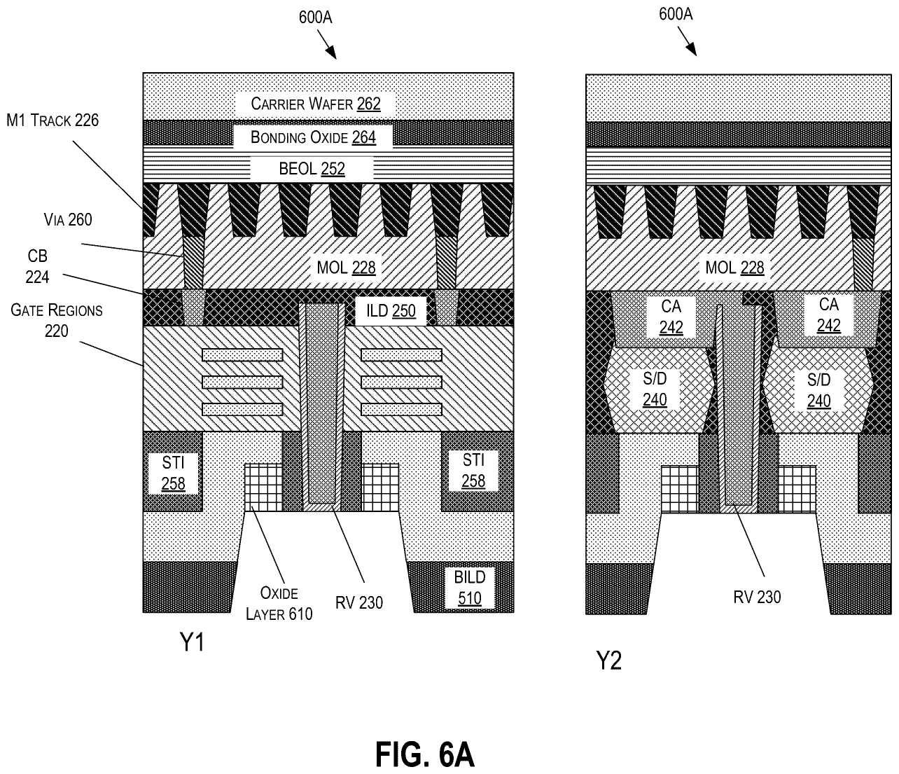

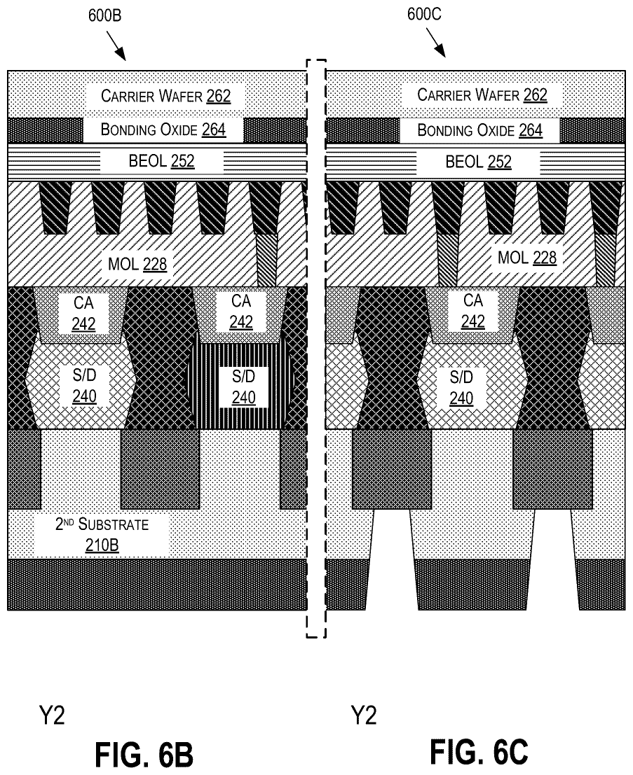

FIGS. 6A-6C illustrate a semiconductor device after the deposition and recess of the oxide layer, in accordance with some embodiments. In some embodiments, the oxide layer 610 is deposited and recessed within the cavities between the second substrate 212B and the STI 258 in the active device 600A.

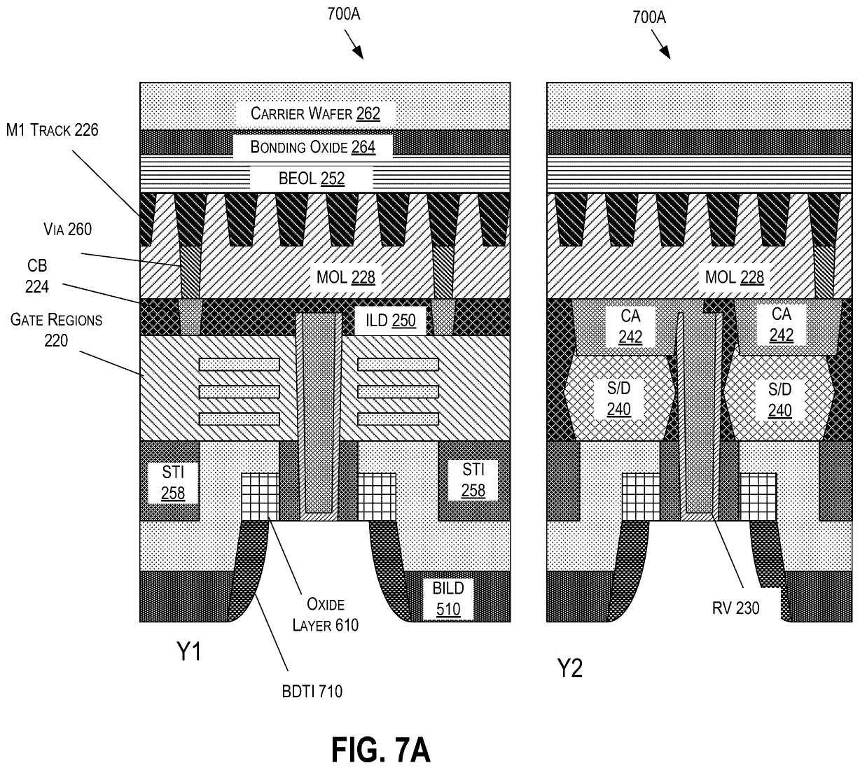

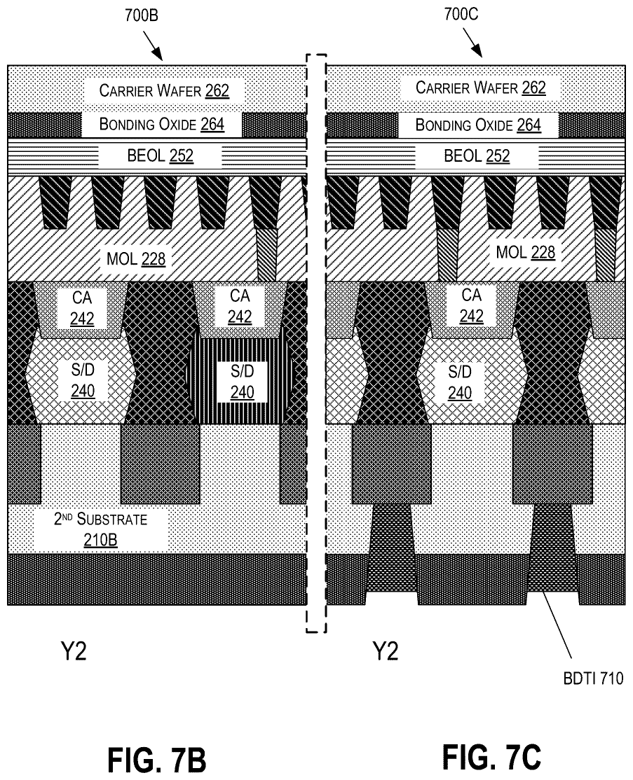

FIGS. 7A-7C illustrate a semiconductor device after the deposition of the backside dielectric trench isolation and breakthrough, in accordance with some embodiments. In some embodiments, the BDTI 710 is formed over the sidewalls of the second substrate 212B, the oxide layer 610, and the BILD 510 in the active device 700A, and over the sidewalls of the second substrate 212B and the BILD 510 in the high voltage region 700C.

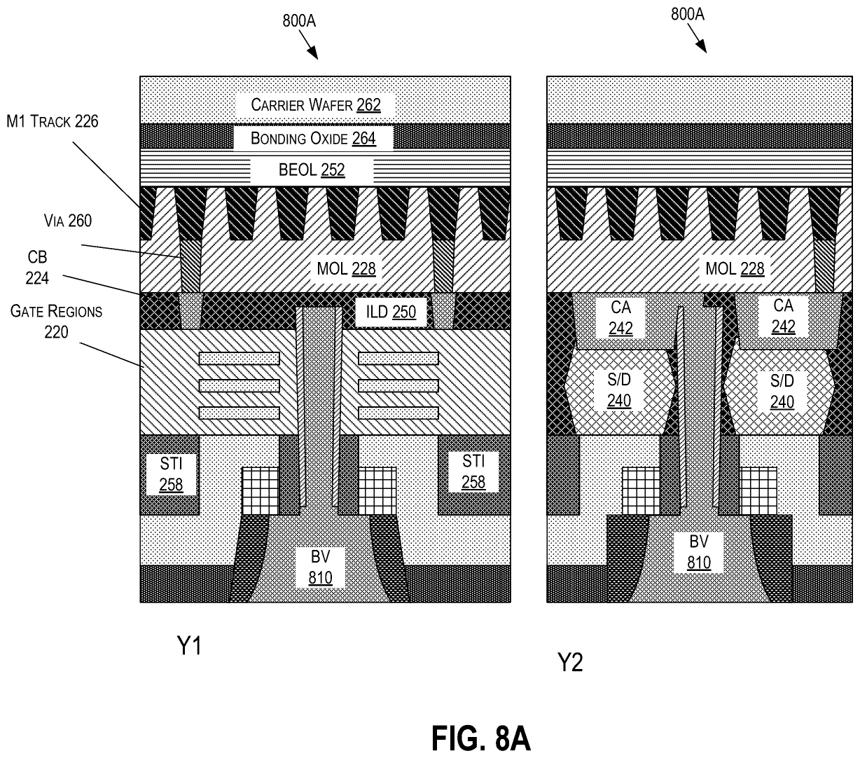

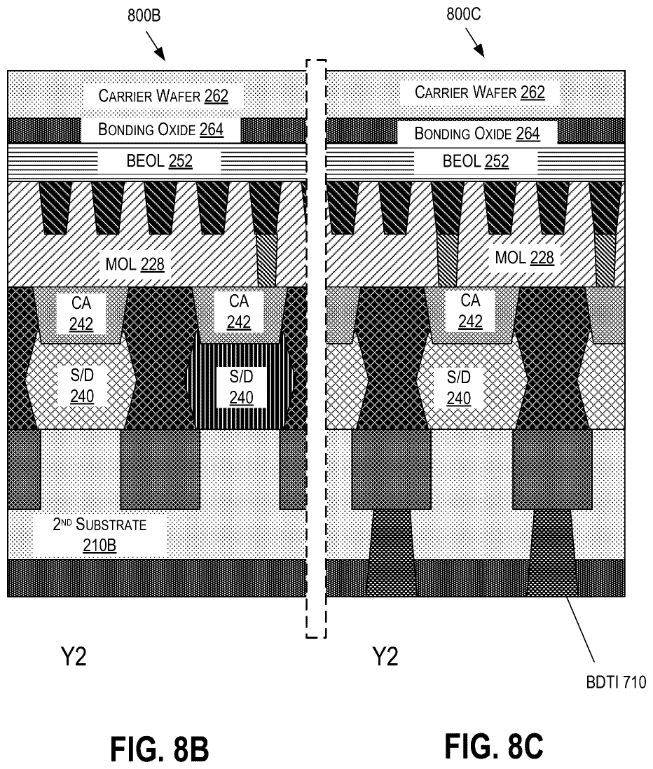

FIGS. 8A-8C illustrate a semiconductor device after the metallization of the backside contact, in accordance with some embodiments. In some embodiments, the cavities within the BDTI 710 are filled with a suitable material to form the BV 810 in the active region 800A, followed by a CMP process.

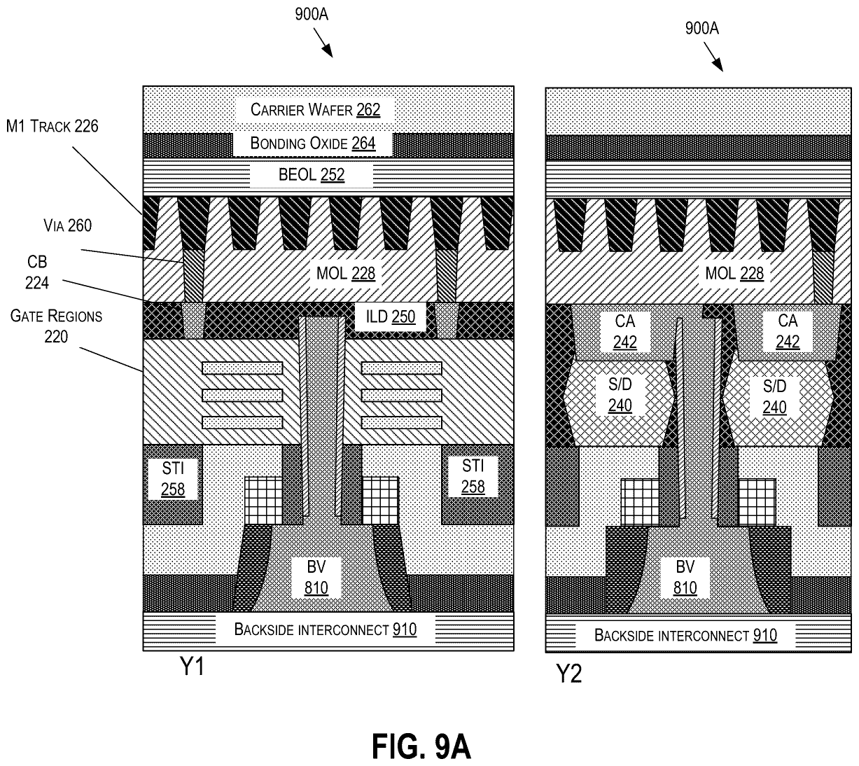

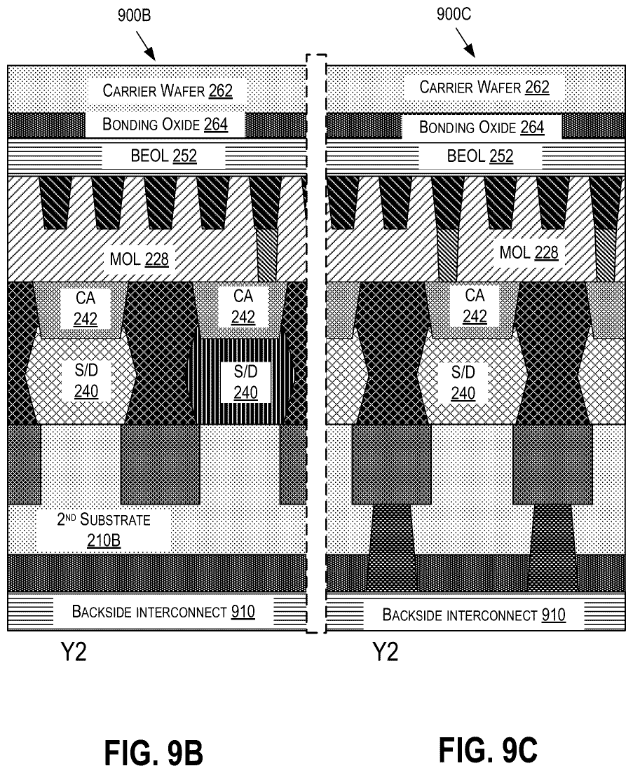

FIGS. 9A-9C illustrate a semiconductor device after the formation of the backside interconnect, in accordance with some embodiments. In some embodiments, the backside interconnect 910 is formed over the BILD 510 in the passive device, over the BILD 510 and the BDTI 710 in the high voltage region 900C, and over the BILD 510, the BDTI 710, and the BV 810 in the active device 900A.

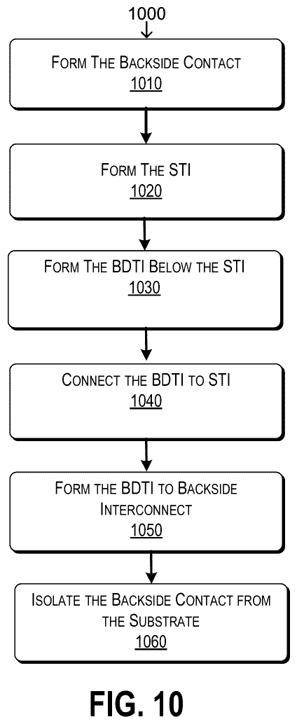

FIG. 10 illustrates a block diagram of a method 1000 for forming the semiconductor device, in accordance with some embodiments. As shown by block 1010, a backside contact is formed.

As shown by block 1020, the STI is formed.

As shown by block 1030, the BDTI is formed below the STI.

As shown by block 1040, a connection between a top surface of the BDTI and the STI on a backside of a high-voltage region of the semiconductor device is established.

As shown by block 1050, a connection between a bottom surface of the BDTI and a backside power interconnect is established.

As shown by block 1060, a backside contact from a substrate by the BDTI is isolated.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a backside contact;
a shallow trench isolation (STI); and
a backside dielectric trench isolation (BDTI) below the STI, wherein:
a top surface of the BDTI is connected to the STI on a backside of a high voltage region of the semiconductor device,
a bottom surface of the BDTI is connected to a backside power interconnect, and
the BDTI isolates a backside contact from a substrate.

2. The semiconductor device of claim 1, further comprising:
a bonding oxide bonding the semiconductor device to a carrier wafer; and
a bottom interlayer dielectric isolating the substrate from contact with the backside power interconnect.

3. The semiconductor device of claim 1, wherein:
the backside contact includes a backside via connected to a frontside via,
the STI covers lower portions of sidewalls of the frontside via, and
the BDTI covers sidewalls of the backside via.

4. The semiconductor device of claim 1, further comprising:
an oxide layer over lower portions of sidewalls of the STI and over the BDTI; and
an insulating layer over sidewalls of a frontside via, wherein:
the insulating layer isolates the frontside via from direct contact with the STI.

5. The semiconductor device of claim 1, further comprising:
a first source/drain region and a second source/drain region over the substrate; and
a second frontside contact connecting the second source/drain region to a back end of line (BEOL) through a via, wherein:
a first frontside contact connects the first source/drain region to a backside of the semiconductor device through a frontside via and the backside via.

6. The semiconductor device of claim 1, wherein the high voltage region is a fin field-effect transistor (FET), a planar device, or a nanosheet transistor.

7. The semiconductor device of claim 1, wherein the bottom surface of the BDTI and a bottom surface of the backside via are coplanar.

8. The semiconductor device of claim 1, further comprising:
a passive device; and
an active device connected to the passive device.

9. The semiconductor device of claim 8, wherein an insulating layer isolates a frontside via from direct contact with gate regions of the active device.

10. A method for fabrication of a semiconductor device, the method comprising:
forming a backside contact;
forming a shallow trench isolation (STI);
forming a backside dielectric trench isolation (BDTI) below the STI;
establishing a connection between a top surface of the BDTI and the STI on a backside of
a high voltage region of the semiconductor device;
establishing a connection between a bottom surface of the BDTI and a backside power interconnect; and
isolating a backside contact from a substrate by the BDTI.

11. The method of claim 10, further comprising:
bonding the semiconductor device to a carrier wafer via a bonding oxide; and
isolating the substrate from contact with the backside power interconnect via a bottom interlayer dielectric.

12. The method of claim 10, wherein: the backside contact includes a backside via connected to a frontside via, the method further comprising:
covering lower portions of sidewalls of the frontside via by the STI, and
covering sidewalls of the backside via by the STI.

13. The method of claim 10, further comprising:
forming an oxide layer over lower portions of sidewalls of the STI and over the BDTI;
forming an insulating layer over sidewalls of a frontside via; and
isolating the frontside via from direct contact with the STI by the insulating layer.

14. The method of claim 10, further comprising:
forming a first source/drain region and a second source/drain region over the substrate;
establishing a connection between the second source/drain region to a back end of line (BEOL) through a second frontside contact and a via; and
establishing a connection between the first source/drain region to a backside of the semiconductor device through a frontside contact, a frontside via and the backside via.

15. The method of claim 10, wherein the high voltage region is a fin field-effect transistor (FET), a planar device, or a nanosheet transistor.

16. The method of claim 10, wherein the bottom surface of the BDTI and a bottom surface of the backside via are coplanar.

17. The method of claim 10, further comprising:
forming a passive device; and
forming an active device connected to the passive device.

18. The method of claim 17, further comprising isolating a frontside via from direct contact with gate regions of the active device by an insulating layer.

19. A semiconductor device, comprising:
a shallow trench isolation (STI); and
a backside dielectric trench isolation (BDTI) below the STI, wherein:
a top surface of the BDTI is connected to the STI on a backside of a high voltage region of the semiconductor device,
a bottom surface of the BDTI is connected to a backside power interconnect, and
the high voltage region is a fin field-effect transistor (FET), a planar device, or a nanosheet transistor.

20. The semiconductor device of claim 19, further comprising a backside contact, wherein the BDTI isolates a backside contact from a substrate.
